(19) United States
(12) Patent Application Publication
(10) Pub. No.: US 2011/0074476 A1
(43) Pub. Date: Mar. 31, 2011

(54) APPARATUS FOR LOCK-IN AMPLIFYING AN INPUT SIGNAL AND METHOD FOR GENERATING A REFERENCE SIGNAL FOR A LOCK-IN AMPLIFIER

(76) Inventors: Flavio Heer, Niederglatt (CH); Sadik Hafizovic, Zurich (CH)

(21) Appl. No.: 12/993,884

(22) PCT Filed: May 27, 2008
(86) PCT No.: PCT/CH2008/000239

§ 371 Date: Nov. 22, 2010

(51) Int. Cl. H03L 7/08

(52) U.S. Cl. 327/156

(57) ABSTRACT

Apparatus (300; 400; 500) for lock-in amplifying an input signal (S_{I}), including one or more lock-in amplifiers (304, 307, 308; 422, 423, 424; 504, 507, 515, 516) with a first input terminal (In) for the input signal (S_{I}) to be lock-in amplified and a second input terminal (Ref) for a reference signal, wherein at least one phase-locked loop circuit (312; 508, 514) is provided, which phase-locked loop circuit (312; 508, 514) comprises one of the one or more lock-in amplifiers (304; 422, 504; 515), an oscillator (306; 506, 511) and a feedback path (303; 421; 503, 517) from the oscillator (306; 506, 511) to the second input (Ref) of the one lock-in amplifier (304; 422, 504; 515), wherein an input terminal of the at least one phase-locked loop circuit (312; 508, 514) is connected with the first input terminal (In) of the one or more lock-in amplifiers (304, 307, 308; 422, 423, 424; 504, 507, 515, 516) and an output terminal of the oscillator (306; 506, 511) is connected to the second input terminal (Ref) of the one or more lock-in amplifiers (304, 307, 308; 422, 423, 424; 504, 507, 515, 516). 7. Further the disclosure relates to a method for generating a reference signal for one or more lock-in amplifiers (304, 307, 308; 422, 423, 424; 504, 507, 515, 516).

### TECHNICAL FIELD

The invention relates to an apparatus for lock-in amplifying an input signal according to the preamble of claim 1 and to a method for generating a reference signal for at least one lock-in amplifier according to the preamble of claim 7.

### BACKGROUND

A lock-in amplifier is known as an amplifier that can recover a signal from an extremely noisy environment (M. L. Meade, “Lock-in Amplifiers: Principles and Applications”, 1983, Peter Peregrinus Ltd., chapter 2, pp. 16). Lock-in amplifiers use frequency mixing to convert the phase and the amplitude of a signal to a DC (direct current) voltage signal. They measure the amplitude of a signal in a very narrow frequency band around a reference frequency, thereby blocking frequency components of the signal which lie outside this frequency band. A lock-in amplifier may also be referred to as frequency-selective voltmeter, AC (alternating current) signal recovery instrument, phase meter, or vector voltmeter. Lock-in amplifiers are often employed as components inside other electric devices such as e.g. spectrum analyzers, network analyzers, noise measurement units, oscillation controllers, phased arrays, and hull curve generators.

FIG. 1 depicts a conventional analog lock-in amplifier 100 with a first input terminal 101 for an input signal S_{I} and a second input terminal 106 for a reference signal S_{R}. The input signal S_{I} typically has one or more signal components, one signal component having a center frequency f₀. The lock-in amplifier 100 comprises a phase detector (PD) 103 and a phase-locked loop (PLL) circuit 110. The phase-locked loop circuit 110 comprises a voltage-controlled oscillator (VCO) 105, a phase detector 107, that is connected via a low-pass loop filter 108 to the voltage-controlled oscillator 105, and a feedback path 111, that connects the voltage-controlled oscillator 105 to the phase detector 107. The phase-locked loop circuit 110 is a closed-loop configuration that minimizes the phase error between the reference signal S_{R} and the output signal of the voltage-controlled oscillator 105. The output signal of the voltage-controlled oscillator 105 is fed back to the phase detector 107, where it is multiplied with the reference signal S_{R}.

The output signal of the voltage-controlled oscillator 105 is also fed to the phase detector 103, which multiplies it with the input signal S_{I}. I.e. the (filtered) input signal S_{I} and the output signal of the voltage-controlled oscillator 105 are mixed. Upstream the phase detector 103 there is typically provided a preamplifier 102 to match the input signal S_{I} more closely to the optimum input signal range of the phase detector 103. The preamplifier 102 may comprise so-called AC coupling. Downstream the phase detector 103 is typically an integrator 104 provided whose output signal constitutes the output signal S_{O} of the lock-in amplifier 100. The output signal S_{O} is essentially a DC signal, where the contribution from any signal component that is not at the same frequency as the reference signal S_{R} is attenuated essentially to zero, as well as an out-of-phase component of the input signal S_{I} with the same frequency as the reference signal S_{R} (confer http://en.wikipedia.org/wiki/Lock-in_amplifier).

Analog lock-in amplifiers often suffer from non-idealities such as drift and temperature dependency and are nowadays increasingly replaced by digital lock-in amplifiers. Analog lock-in amplifiers usually provide little information on the harmonics of the input signal due to their sensitivity to interferences at odd harmonics and their inherent non-linearity. Further, two analog lock-in amplifiers are required to concurrently measure a time-periodic input signal in phase and in quadrature with the reference signal. Furthermore, two additional analog lock-in amplifiers are needed for measuring the signal component due to a harmonic frequency, i.e. for a second channel.

With a digital lock-in amplifier all calculations are done with digital numbers and are essentially error-free provided that the bit-length is chosen long enough to avoid quantization errors. Typically, the main error source is the employed A/D (analog-to-digital) converter. With respect to overall performance digital lock-in amplifiers can easily reach a dynamic reserve above 100 dB, whereas analog lock-in amplifiers can typically only reach a maximum dynamic reserve of about 60 dB.

FIG. 2 shows a typical digital lock-in amplifier 200 with a first input terminal 209 for an input signal S_{I} and a second input terminal 210 for a reference signal S_{R}. In principle, the digital lock-in amplifier 200 corresponds to the analogue lock-in amplifier 100 depicted in FIG. 1 but with the input signal S_{I} and the reference signal S_{R} being converted to discrete-time/digital signals before demodulation by the phase detector 202. The remaining operations correspond to those of the analog lock-in amplifier 100 but take place in the discrete-time domain/digital domain. The digital lock-in amplifier 200 comprises like the analog lock-in amplifier 100 (see FIG. 1) a phase detector 202 and a phase-locked loop circuit 211. The phase-locked loop circuit 211 comprises also a phase detector 205, a numerically-controlled oscillator 204 (NCO) and a feedback path 212 from the numerically-controlled oscillator 204 to the phase detector 205. The numerically-controlled oscillator 204 represents a discrete-time equivalent of the voltage-controlled oscillator 105. A low-pass loop filter 206 is connected ahead of the numerically-controlled oscillator 204.

The output signal of the numerically-controlled oscillator 204 is multiplied by the phase detector 202 with the digitized input signal. For digitizing the analogue input signal S_{I} an A/D converter 201 is provided upstream the phase detector 202. Downstream the phase detector 202 an integrator 203 is provided whose output signal constitutes the output signal S_{O} of the lock-in amplifier 200. For digitizing the analogue reference signal S_{R} usually just a comparator 208 is provided upstream the phase detector 205.

Performing the operations in the discrete-time domain has the advantages that errors due to drift problems, non-linearities and non-idealities are basically non-existent in the performed operations, in particular in the multiplication and integration operations. Consequently, the overall performance which reflects itself e.g. in the dynamic reserve and the phase angle accuracy can be largely improved (see e.g. U.S. Pat. No. 4,807,146, U.S. Pat. No. 4,914,677, Cova et al., “Versatile digital lock-in detection technique: Application to spectrofluorometry and other fields”, Review of Scientific Instruments, vol. 50, pp. 296, 1979, Optronics Laboratory, “The Benefits of DSP Lock-in Amplifiers”, Application Note (A12), 1996).

In many applications a reference signal is either not available or it is difficult to access. In these cases it is one approach to process the input signal by considering a wide frequency band to ensure that the signal of interest is inside this frequency band. The drawback of this approach is, however, that the noise inside this frequency band will also be recovered and form part of the output signal thereby reducing the quality of the signal processing.

By employing a phase-locked loop circuit for tracking the input signal frequency, the frequency band and hence the noise bandwidth can be narrowed. However, a conventional lock-in amplifier requires an input signal S_{I} and a reference signal S_{R}. The reference signal S_{R} is used to adjust the internal oscillator of the phase-locked loop circuit (confer the above description of FIGS. 1 and 2). This reference signal S_{R} is generally required to have a signal-to-noise ratio larger than 1. Often it is required to be suitable for TTL (transistor-transistor-logic) level. If such a reference signal is not accessible, then the internal oscillator of the phase-locked loop circuit has to be tuned in another way (US 2007/026830 A1).

In Perkin Elmer Instruments/Signal Recovery, “The digital lock-in amplifier”, Technical Note TN1003, V2.0, 2000, it is proposed to generate a so-called virtual reference to be used as reference signal. For generating this virtual reference the imaginary part of the demodulated input signal of the lock-in amplifier (usually referred to as Y channel output signal) is used to adjust the internal frequency and phase of the oscillator to achieve a phase-lock with the applied input signal. The imaginary part is minimized by using a feedback loop. At the same time the real part of the demodulated input signal of the lock-in amplifier (usually referred to as X or in-phase channel output signal) can be maximized. This approach has the disadvantage that only the signal amplitude of one single frequency of the input signal can be recovered, whereas recovery of the entire input signal from a noisy environment with complete amplitude and phase information for all relevant frequencies including harmonics is not possible.

### DISCLOSURE OF THE INVENTION

It is an object of the invention to provide an apparatus for lock-in amplifying an input signal and a method for generating a reference signal for at least one lock-in amplifier by which the above-mentioned drawbacks of the state of the art can be avoided.

In order to implement these and still further objects of the invention, which will become more readily apparent as the description proceeds, an apparatus for lock-in amplifying an input signal, which comprises one or more lock-in amplifiers with a first input terminal for the input signal to be lock-in amplified and a second input terminal for a reference signal and at least one phase-locked loop circuit, is provided. The phase-locked loop circuit comprises one of the one or more lock-in amplifiers, an oscillator and a feedback path from the oscillator to the second input terminal of the one lock-in amplifier, wherein an input terminal of the at least one phase-locked loop circuit is connected with the first input terminal of the one or more lock-in amplifiers and an output terminal of the oscillator is connected to the second input terminal of the one or more lock-in amplifiers. The frequency of the oscillator is variable.

Furthermore a method for generating a reference signal for one or more lock-in amplifiers is provided, wherein an input signal for the one or more lock-in amplifiers is fed to the first input terminal of one of the one or more lock-in amplifiers which forms part of at least one phase-locked loop circuit, which furthermore comprises an oscillator and a feedback path from the oscillator to the second input terminal of the one lock-in amplifier, and wherein the reference signal is given by the output signal of the oscillator.

With the proposed apparatus and method a reference signal for a lock-in amplifier can be generated from the input signal itself such that advantageously no additional external signal is required. This leads to a reduction of the complexity of the measurement setup and to an improvement of signal quality. With the phase-locked loop circuit the center frequency of the input signal can be tracked and an output signal with this frequency, which is generated by the oscillator of the phase-locked loop circuit, is then used as reference signal for the one or more lock-in amplifiers.

Furthermore, harmonics analysis (also referred to as octave analysis) of an input signal buried in noise can be performed by means of the apparatus and the method according to the invention. For this the apparatus of the invention locks on the fundamental frequency of the input signal and analyzes several harmonics. If the apparatus is designed as digital apparatus it can perform real-time operations with trigger functions being used on the fundamental frequency as well as on the harmonic frequencies.

If two input signals, whose amplitudes lie preferentially below the noise level, shall be processed by the apparatus according to the invention, one of the input signals is preferably used for generation of the reference signal by means of the phase-locked loop circuit to be used as second input signal of the one or more lock-in amplifiers.

### BRIEF DESCRIPTION OF THE DRAWINGS

Further advantageous features and applications of the invention can be found in the depending claims as well as in the following description of the drawings illustrating the invention. In the drawings like reference signs designate the same or similar parts throughout the several figures of which:

FIG. 1 depicts a block diagram of an analog lock-in amplifier according to the state of the art,

FIG. 2 depicts a block diagram of a digital lock-in amplifier according to the state of the art,

FIG. 3 depicts a block diagram of a first embodiment of an apparatus according to the invention,

FIG. 4 depicts a block diagram of a second embodiment of an apparatus according to the invention,

FIG. 5 depicts a block diagram of a third embodiment of an apparatus according to the invention,

FIG. 6 depicts a block diagram of the third embodiment shown in FIG. 5 supplemented by an arithmetic unit.

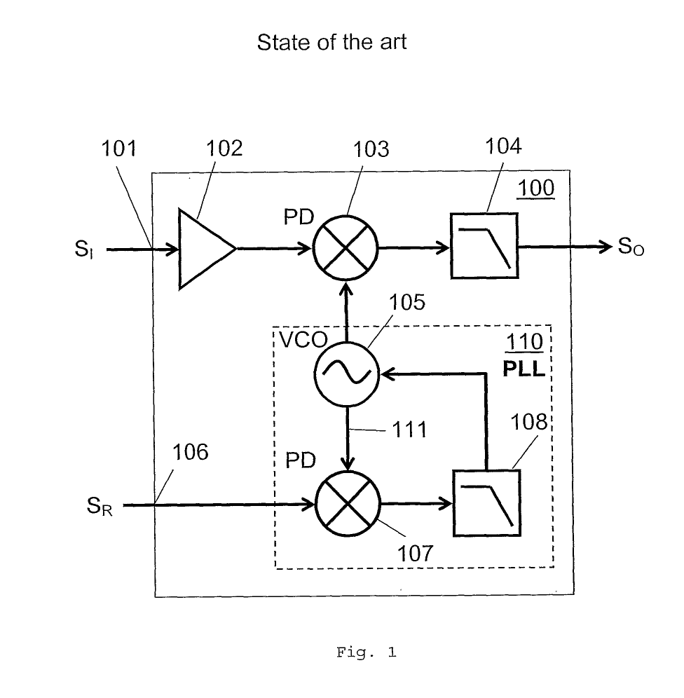

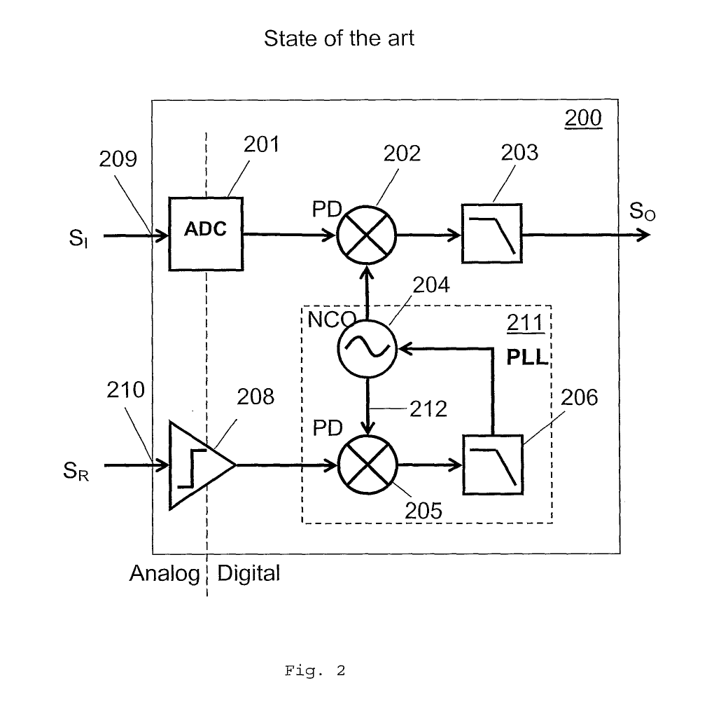

FIGS. 1 and 2 have already been described in the introductory part of the description and it is referred thereto.

### MODES FOR CARRYING OUT THE INVENTION

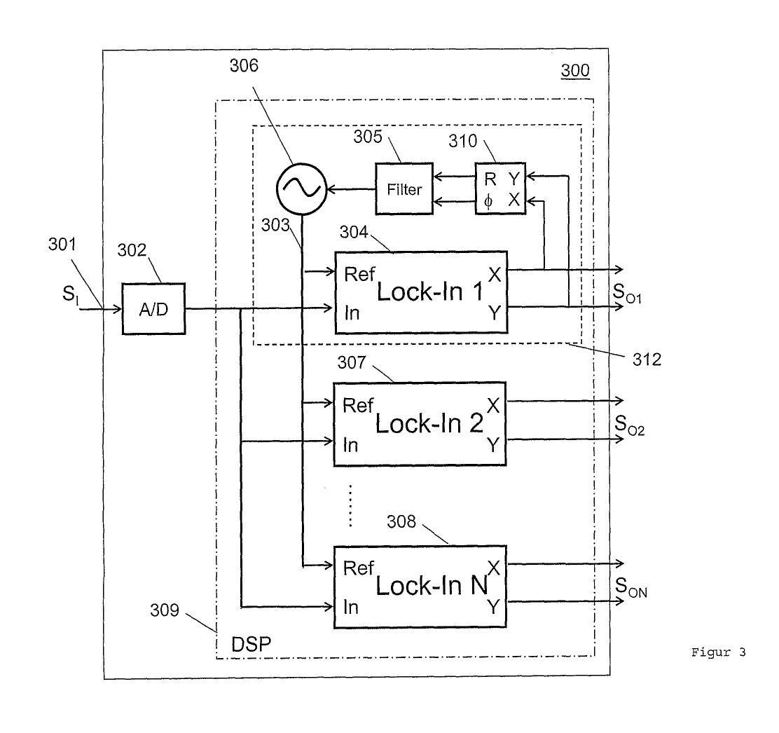

FIG. 3 shows as first preferred embodiment of an apparatus according to the invention an apparatus 300 for lock-in amplifying an input signal S_{I}. The apparatus 300 has an input terminal 301 for the input signal S_{I}. The apparatus 300 is preferably a digital apparatus with an A/D converter 302 for digitizing the input signal S_{I}. Also so-called intelligent digital filters (non-depicted) may be used to preprocess the input signal and to suppress undesired signal components.

One or more lock-in amplifiers 304, 307, 308 are provided, which may correspond to the conventional analog lock-in amplifier 100 depicted in FIG. 1 (analog case) or to the digital lock-in amplifier 200 depicted in FIG. 2 (digital case). The digitized input signal is fed to a first input terminal (In) of the one or more lock-in amplifiers 304, 307, 308.

Furthermore, the apparatus 300 comprises a phase-locked loop circuit 312 with lock-in amplifier 304, an oscillator 306 whose frequency is variable and a feedback path 303 from the oscillator 306 to the second input terminal (Ref) of the lock-in amplifier 304. From the lock-in amplifier 304 the signal is preferably fed via a low-pass (loop) filter 305 to the oscillator 306. Of course, other filter types can be used for the filter 305 and for further down mentioned filters as e.g. a PID (proportional-integral-difference)-filter. Preferably upstream the filter 305 a Cartesian-to-polar coordinate converter 310 is provided. The output signal from the oscillator 306 is fed back to the second input terminal Ref of the lock-in amplifier 304 and it is furthermore fed to a second input terminal (Ref) of the lock-in amplifiers 307, 308 as reference signal. Hence, the same signal is applied/multiplexed as reference signal to the one or more lock-in amplifiers 304, 307, 308 as reference signal resulting in the output signals S_{O1} to S_{ON} of the one or more lock-in amplifiers 304, 307, 308. Each lock-in amplifier 304, 307, 308 represents one channel and all signals on these channels are essentially phase-synchronous to each other and to the input signal S_{I} due to the generation and provision of the one reference signal.

In case of the apparatus 300 being a digital apparatus all components/blocks 307, 308, 312 apart from the A/D converter 302 may be implemented in one digital signal processor (DSP) 309 and/or field-programmable gate array (FPGA). Of course, any other, preferably programmable, digital can be employed. As all processed signals originate from the A/D converter 302 essentially no additional inaccuracies occur which may be caused by the use of several components, mismatch between different input signals, drift or temperature dependency. Digital signals bear the advantage that they are inherently error-free regarding amplitude and phase provided that the corresponding bit-length is chosen long enough to avoid quantization errors. The reduced non-linearity and the reduced occurrence of amplitude and phase errors lead to an increased precision of the performed signal processing.

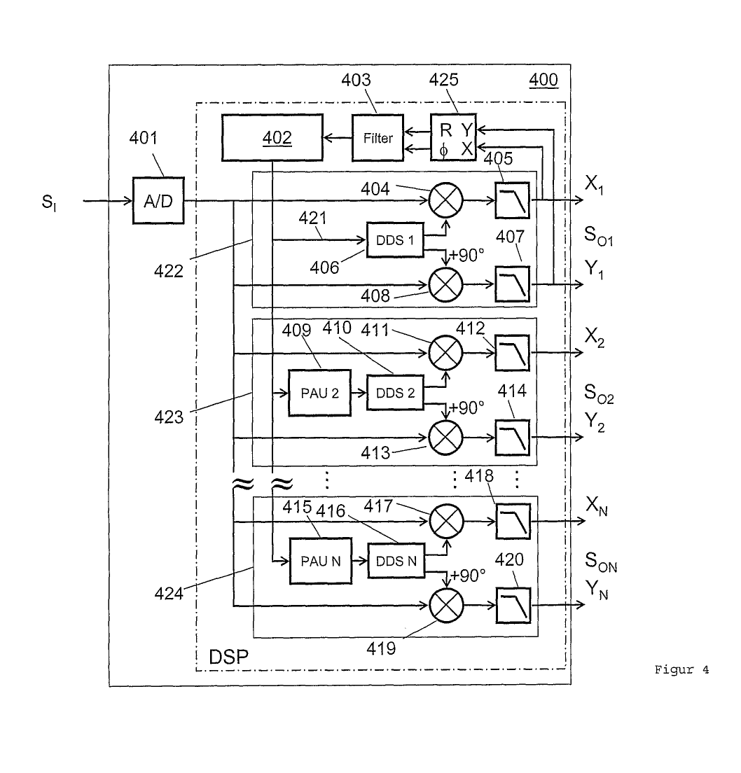

FIG. 4 shows a further embodiment of the apparatus according to invention as the digital apparatus 400. An input signal S_{I} is fed to an input terminal 401 of the apparatus 400 and digitized by an A/D converter 402 which is in particular a high-speed A/D converter. All further processing is done in the discrete-time/digital domain and, hence, makes use of the thus provided accuracy of digital signal processing. The digitized input signal is fed to the phase detectors 404, 408 which form part of a phase-locked loop circuit further comprising a low-pass (loop) filter 403, a phase accumulator 402 and feedback paths 421 to the phase detectors 404, 408 wherein the feedback paths 421 comprise a first direct digital synthesizer (DDS) 406. Upstream the filter 403 a Cartesian-to-polar coordinate converter 425 may be provided. Direct digital synthesis is an electronic method for digitally creating arbitrary frequencies from a single, fixed-source frequency (http://en.wikipedia.org/wiki/Direct_Digital_Synthesis). The phase accumulator 402 and the direct digital synthesizer 406 essentially represent the oscillator of the phase-locked loop circuit. By means of the phase detectors 404, 408, the optional Cartesian-to-polar coordinate converter 425, the low-pass loop filter 403, the phase accumulator 402 and the feedback paths 421 with the first direct digital synthesizer 406 the operation of a phase-locked loop circuit is performed such that the input signal S_{I} can be tracked at a specific frequency of interest, so that the signal component with this specific frequency can be extracted by a lock-in amplifier 422.

The output signal of the phase detectors 404, 408 is fed to and smoothed by the low-pass loop filter 403 and afterwards applied to the phase accumulator 402. The output signal of the phase accumulator 402 is then applied to the first direct digital synthesizer 406 and the output signal of the first direct digital synthesizer 406 is thereafter applied to the phase detectors 404, 408 to be multiplied with the digitized input signal.

The apparatus 400 depicted in FIG. 4 comprises several lock-in amplifiers 422, 423, 424, each comprising two phase detectors 404 and 408, 411 and 413, and 417 and 419, respectively, which are connected downstream preferably with integrators 405, 407, 412, 414, 418, 420, and direct digital synthesizers 406, 410, 416. The integrators 405, 407, 412, 414, 418, 420 are preferably given by low-pass filters or as another type of filter. The digitized input signal is fed to all phase detectors 404, 408, 411, 413, 417, 419 where it is multiplied with the output signal of the respective direct digital synthesizer 406, 410, 416, which constitutes the reference signal.

The output signal of the phase accumulator 402 is fed either directly or indirectly to the respective direct digital synthesizer 406, 410, 416. For the latter case it is fed via a phase arithmetic unit (PAU) 409, 415 to the respective direct digital synthesizer 410, 416. This is in particular the case for lock-in amplifiers 423, 424 which are arranged in parallel to the first lock-in amplifier 422.

The depicted lock-in amplifiers 422, 423, 424 are dual phase lock-in amplifiers by which dual phase measurements can be performed as two simultaneously measurements are taken, one by a first phase detector 404, 411, 417 with the reference phase (i.e. the phase of the reference signal) equal to that of the input signal S_{I} and one by a second phase detector 408, 413, 419 with the reference phase shifted by 90 degrees from that of the input signal S_{I}. This is illustrated in FIG. 4 by the notation “+90°”. Such, both the magnitude and the phase of the input signal S_{I} can be calculated. The output signals of the first phase detectors 404, 411, 417 are called X (channel) output signals and the output signals of the second phase detectors are called Y (channel) output signals.

The phase detectors 404, 408 and the first direct digital synthesizer 406 also perform the required operations of a phase-locked loop circuit, i.e. the phase detectors 404, 408 and the first direct digital synthesizer 406 are shared between the first lock-in amplifier 422 and a phase-locked loop circuit.

As several lock-in amplifiers 422, 423, 424 are provided they can advantageously be used to demodulate the input signal S_{I} at various frequencies. For example, the second lock-in amplifier 423 may be used to measure the input signal S_{I} at the first harmonic. For this the output signal from the phase accumulator 402 is fed as reference signal via the phase arithmetic unit 409 and the second direct digital synthesizer 410 to the phase detectors 411 and 413 to be multiplied with the digitized input signal. For this case the phase arithmetic unit 409 has a multiplication factor of 2. The phase arithmetic unit 409 (and correspondingly the phase arithmetic unit 415 of the lock-in amplifier 424) performs essentially error-free arithmetic operations of the phase, in particular multiplications (for harmonics generation) or delays (phase shifting). Hence, by means of the second lock-in amplifier 423 the input signal S_{I} may be analyzed at a second frequency corresponding to basically twice the center frequency f₀ of the input signal S_{I}.

The several lock-in amplifiers 422, 423, 424 may also be employed for analyzing the input signal S_{I} at the same frequency f₀ but with the bandwidth of the low-pass filters 405, 407, 412, 414, 418, 420 being different for each lock-in amplifier 422, 423, 424, i.e. the low-pass filters 412, 414 having a different bandwidth than the low-pass filters 405, 407. In such a way signal components with different time-constants/time periods can be analyzed by the different lock-in amplifiers representing different channels and thus slow and fast variations can be simultaneously analyzed with optimized signal-to-noise ratios.

All components/blocks apart from the A/D converter 401 may be implemented in a field-programmable gate array (FPGA) 425 and/or as a digital signal processor (DSP) and/or any other, preferably programmable, digital device. For analyzing an input signal with respect to several frequencies also several apparatus according to the invention may be used.

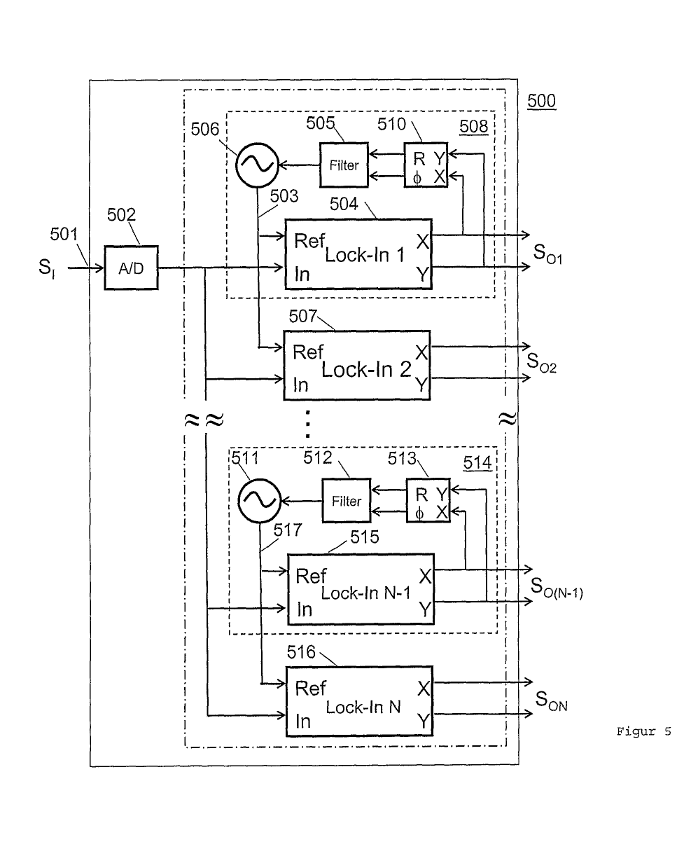

FIG. 5 depicts a further embodiment of an apparatus 500 according to the invention with an input terminal 501 for an input signal S_{I}. An A/D converter 502 is provided for digitizing the analog input signal S_{I}. The apparatus 500 comprises several lock-in amplifiers 504, 507, 515, 516. To the lock-in amplifiers 507, 516 is assigned a phase-locked loop circuit 508, 514. Each phase-locked loop circuit 508, 514 comprises a lock-in amplifier 504, 515, an oscillator 506, 512 and a feedback path 503, 517 connecting the oscillator 506, 511 to respective second input terminal Ref of the corresponding lock-in amplifier 504, 515. Each lock-in amplifier 504, 515 is preferably connected to its respective oscillator 506, 512 via an optional Cartesian-to-polar coordinate converter 510, 513 and a low-pass (loop) filter 505, 512. The output terminal of the oscillator 506, 511 of a particular phase-locked loop circuit 508, 514 is connected to the second input terminal (Ref) of the corresponding lock-in amplifier 504, 507, 515, 516. The output signal of the A/D converter 502 is fed to the first input terminal (In) of all lock-in amplifiers 504, 507, 515, 516. Hence, just one A/D converter 502 is required.

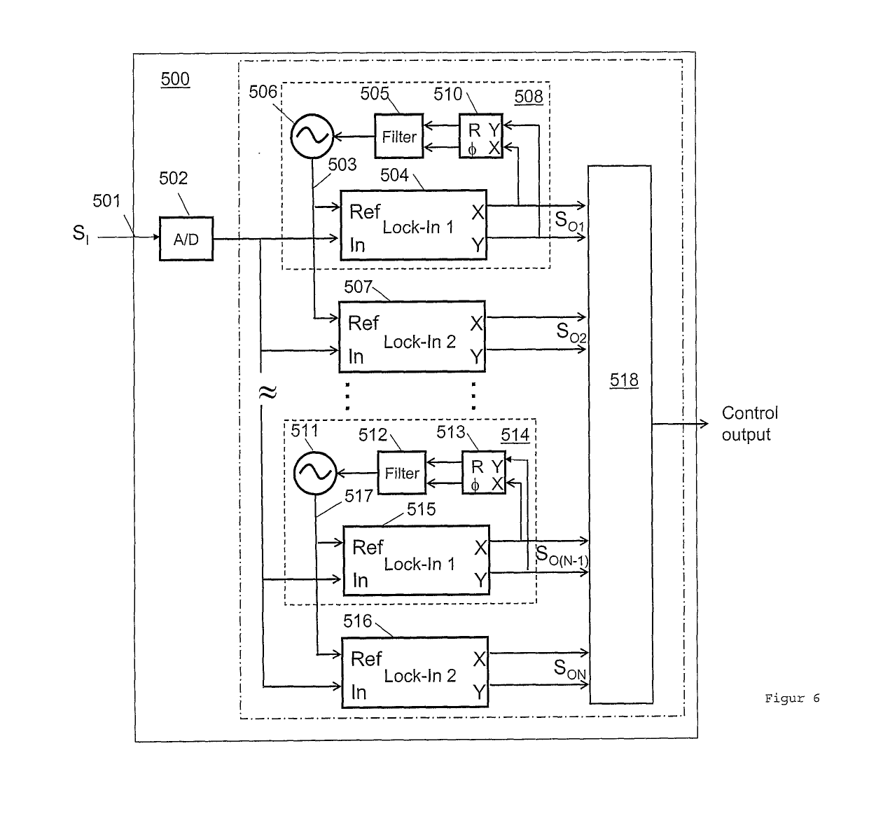

With the apparatus 500 a first phase-locked loop circuit 508 can phase-lock on a first frequency f₁ and thereby lock-in operations on this first frequency f₁ (and if applicable harmonics) can be performed. A second phase-locked loop circuit 514 can phase-lock on a second frequency f₂ of the input signal S_{I}, the second frequency f₂ being different from the first frequency f₁, and the lock-in amplifier 516 can measure the input signal S_{I} at this second frequency f₂. Correspondingly, further phase-locked loop circuits for phase-locking on further frequencies can be provided so that the input signal S_{I} can be analyzed at these further frequencies by means of the corresponding lock-in amplifiers. Furthermore, phase-related correlations between the various frequencies (and their corresponding signal components, respectively) can be performed with high precision for example by an arithmetic unit 518 depicted in FIG. 6. The arithmetic unit 518 analyzes the output signals S_{O1}, S_{O2}, S_{O(N-1)}, S_{ON} of the various lock-in amplifiers 507, 516. FIG. 6 shows the apparatus 500 depicted in FIG. 5 supplemented by the arithmetic unit 518 for analyzing the output signals S_{O1}, S_{O2}, S_{O(N-1)}, S_{ON}. In case of the apparatus 500 being a digital apparatus all components/blocks apart from the A/D converter 502 may be implemented in one digital signal processor (DSP) 517 and/or on field programmable gate array (FGPA) and/or any other, preferably programmable, digital device.

It is to be understood that while certain embodiments of the present invention have been illustrated and described herein, it is not to be limited to the specific embodiments described and shown.

1. Apparatus for lock-in amplifying an input signal (S_{I}), comprising one or more lock-in amplifiers with a first input terminal (In) for the input signal (S_{I}) to be lock-in amplified and a second input terminal (Ref) for a reference signal, wherein at least one phase-locked loop circuit is provided, which phase-locked loop circuit comprises one of the one or more lock-in amplifiers, an oscillator and a feedback path from the oscillator to the second input terminal (Ref) of the one lock-in amplifier, wherein an input terminal of the at least one phase-locked loop circuit is connected with the first input terminal (In) of the one or more lock-in amplifiers and an output terminal of the oscillator is connected to the second input terminal (Ref) of the one or more lock-in amplifiers.

2. Apparatus according to claim 1, wherein several lock-in amplifiers are provided, wherein the output terminal of the oscillator is connected to the second input terminals of all lock-in amplifiers.

3. Apparatus according to claim 1, wherein several phase-locked loop circuits are provided and that to each phase-locked loop circuit are assigned several lock-in amplifiers.

4. Apparatus according to claim 1, wherein the apparatus is a digital apparatus and that the oscillator of the at least one phase-locked loop circuit comprises a phase accumulator and a direct digital synthesizer for each lock-in amplifier.

5. Apparatus according to claim 4, wherein the phase-locked loop circuit and one lock-in amplifier share the phase detectors and/or the direct digital synthesizer.

6. Apparatus according to claim 4, wherein a phase arithmetic unit is connected ahead of at least some of the direct digital synthesizers.

7. Method for generating a reference signal for one or more lock-in amplifiers, wherein an input signal for the one or more lock-in amplifiers is fed to one of the one or more lock-in amplifiers which forms part of at least one phase-locked loop circuit furthermore comprising an oscillator and a feedback path from the oscillator to the second input terminal (Ref) of the one lock-in amplifier, and that the reference signal is given by the output signal of the oscillator.

8. Method according to claim 7, wherein the input signal is fed to the second input (Ref) of the lock-in amplifier of several phase-locked loop circuits, each phase-locked loop circuit being assigned to one or several lock-in amplifiers, and that the reference signal for the one or several lock-in amplifiers is given by the output of the oscillator of the assigned phase-locked loop circuit.
